(19) United States
(12) Patent Application Publication
(10) Pub. No.: US 2025/0107163 A1
(43) Pub. Date: Mar. 27, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kazuyuki SATO, Nonoichi Ishikawa (JP)

(21) Appl. No.: 18/602,569

(22) Filed: Mar. 12, 2024

(30) Foreign Application Priority Data
Sep. 22, 2023 (JP) 2023-158386

(51) Int. Cl. H01L 29/06; H01L 23/522; H01L 23/528; H01L 29/423; H01L 29/78

(52) U.S. Cl. CPC H10D 62/102; H01L 23/5283; H10D 30/665; H10D 64/514; H01L 23/5222

(57) ABSTRACT

A semiconductor device includes a first electrode, a semiconductor part located on the first electrode, an insulating member located in the semiconductor part, a first insulating film located on a portion of the semiconductor part, a second insulating film located on another portion of the semiconductor part, a second electrode located in the insulating member, a first wiring part connected to the second electrode, and a third electrode located on the semiconductor part, on the insulating member, and on the first insulating film. The second insulating film is thicker than the first insulating film. The first wiring part is located on the insulating member and on the second insulating film but not on the first insulating film.

### CROSS-REFERENCE TO RELATED APPLICATIONS

This application is based upon and claims the benefit of priority from Japanese Patent Application No. 2023-158386, filed on Sep. 22, 2023; the entire contents of which are incorporated herein by reference.

### FIELD

Embodiments described herein relate generally to a semiconductor device.

### BACKGROUND

In a vertical power control semiconductor device, there are cases where a gate electrode is located in a trench. It is desirable to reduce the leakage current in the off-state of such a semiconductor device.

### BRIEF DESCRIPTION OF THE DRAWINGS

FIG. 1 is a plan view showing a semiconductor device according to an embodiment;

FIG. 2 is a cross-sectional view along line A-A′ shown in FIG. 1;

FIG. 3 is a cross-sectional view along line B-B′ shown in FIG. 1;

FIG. 4 is a cross-sectional view along line C-C′ shown in FIG. 1;

FIG. 5 is a cross-sectional view along line D-D′ shown in FIG. 1;

FIG. 6 is a cross-sectional view along line E-E′ shown in FIG. 1;

FIG. 7 is a cross-sectional view along line F-F′ shown in FIG. 1;

FIG. 8 is a cross-sectional view along line G-G′ shown in FIG. 1;

FIG. 9 is a plan view showing a semiconductor device according to a comparative example;

FIG. 10 is a cross-sectional view along line H-H′ shown in FIG. 9; and

FIG. 11 is a cross-sectional view along line I-I′ shown in FIG. 9.

### DETAILED DESCRIPTION

In general, according to one embodiment, a semiconductor device includes a first electrode, a semiconductor part located on the first electrode, an insulating member located in the semiconductor part, a first insulating film located on a portion of the semiconductor part, a second insulating film located on another portion of the semiconductor part, a second electrode located in the insulating member, a first wiring part connected to the second electrode, and a third electrode located on the semiconductor part, on the insulating member, and on the first insulating film. The second insulating film is thicker than the first insulating film. The first wiring part is located on the insulating member and on the second insulating film but not on the first insulating film.

### Embodiment

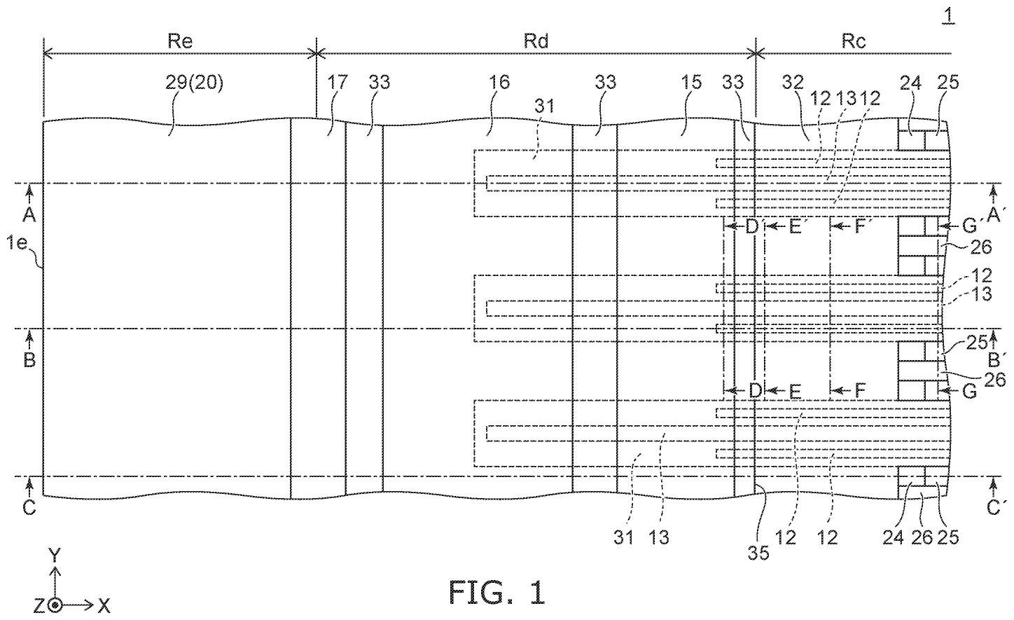

FIG. 1 is a plan view showing a semiconductor device according to the embodiment.

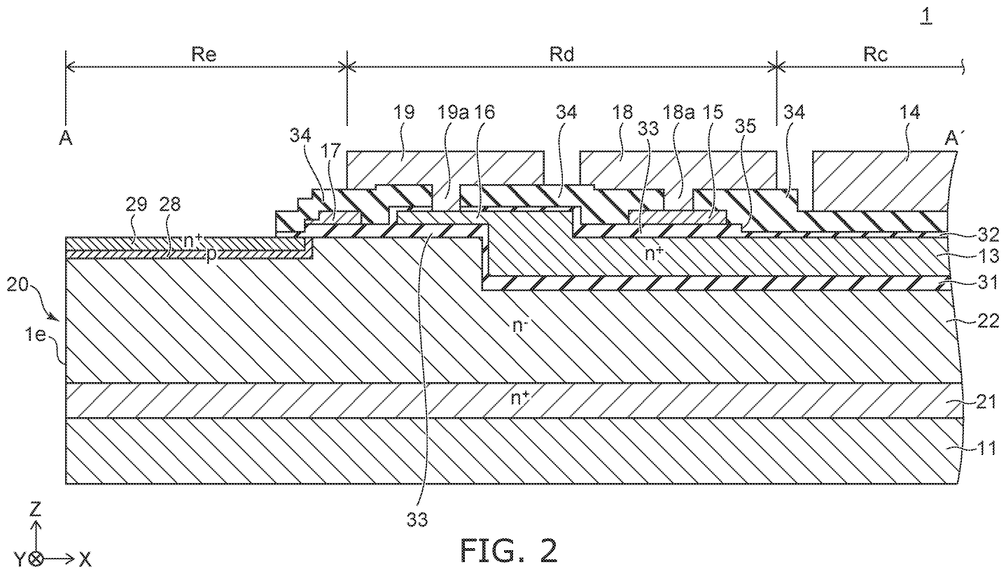

FIG. 2 is a cross-sectional view along line A-A′ shown in FIG. 1.

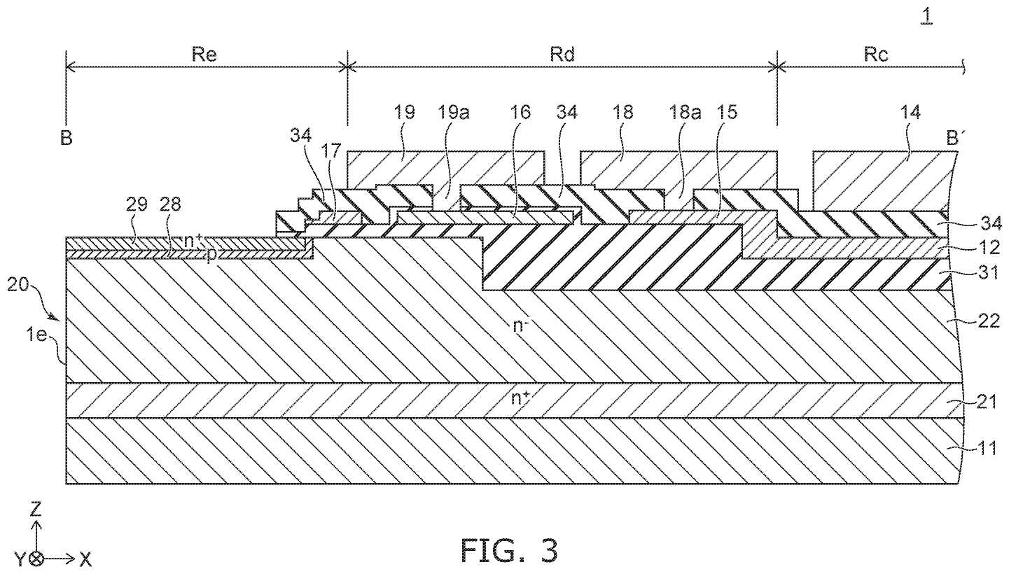

FIG. 3 is a cross-sectional view along line B-B′ shown in FIG. 1.

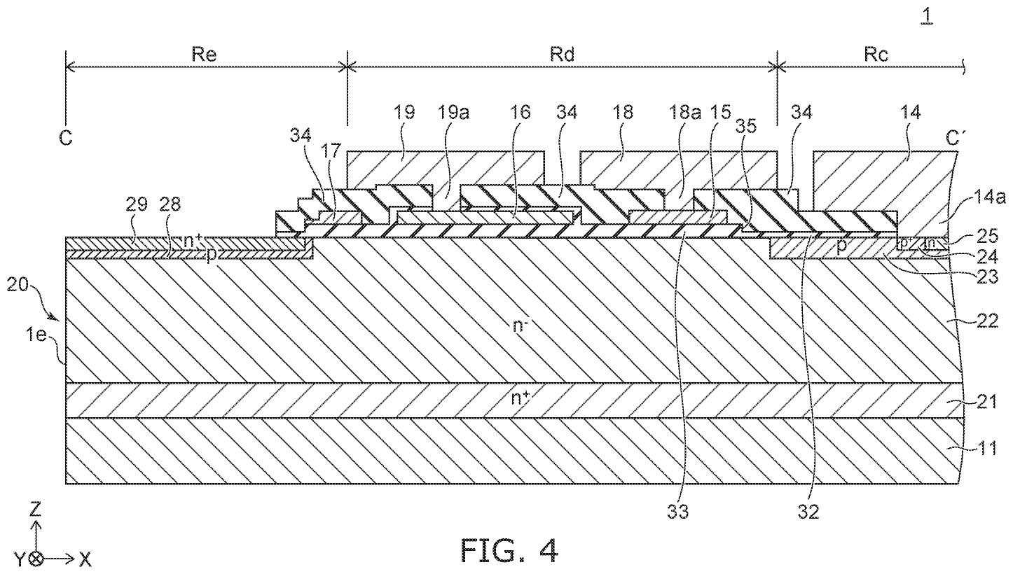

FIG. 4 is a cross-sectional view along line C-C′ shown in FIG. 1.

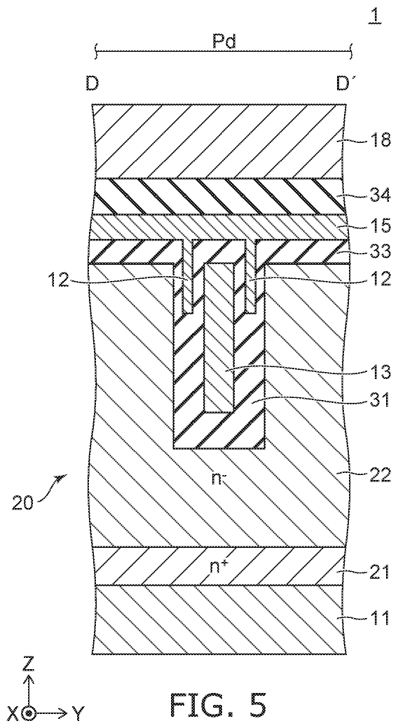

FIG. 5 is a cross-sectional view along line D-D′ shown in FIG. 1.

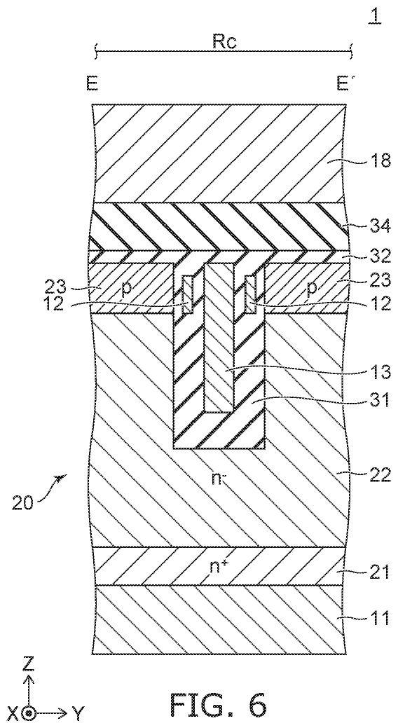

FIG. 6 is a cross-sectional view along line E-E′ shown in FIG. 1.

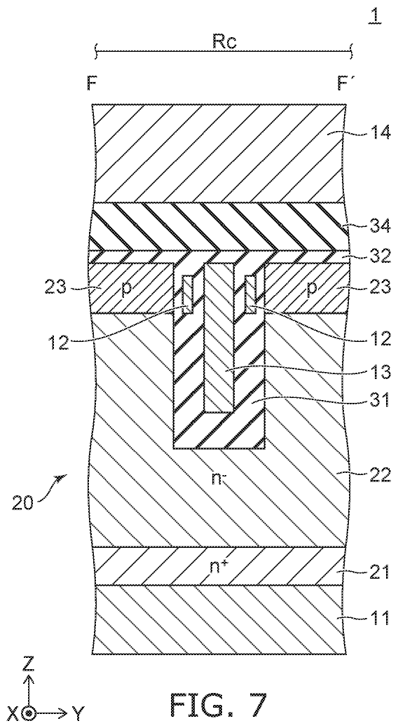

FIG. 7 is a cross-sectional view along line F-F′ shown in FIG. 1.

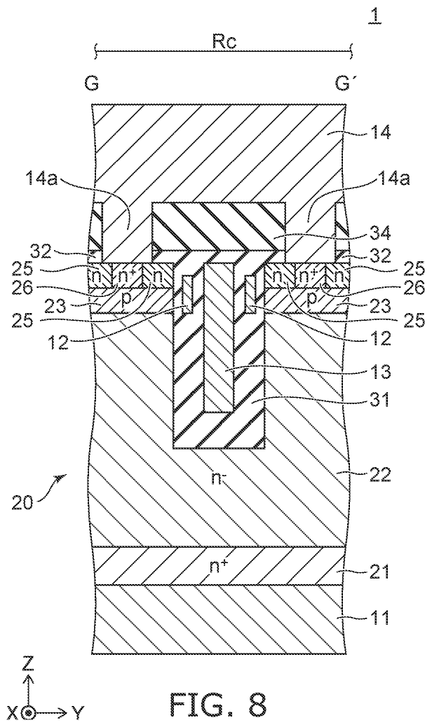

FIG. 8 is a cross-sectional view along line G-G′ shown in FIG. 1.

The drawings are schematic or conceptual, and are enhanced or simplified as appropriate. The dimensional ratios and/or numbers are not necessarily the same between drawings, even for identical components.

As shown in FIGS. 1 to 8, a cell region Rc, a draw-out region Rd, and a termination region Re are set in the semiconductor device 1 according to the embodiment. The termination region Re is located in a frame shape along an edge 1e of the semiconductor device 1. The cell region Rc is surrounded with the termination region Re. The draw-out region Rd is located in a portion of the region between the termination region Re and the cell region Rc.

The semiconductor device 1 includes a drain electrode 11 (a first electrode), a semiconductor part 20, a gate electrode 12 (a second electrode), a FP (field plate) electrode 13 (a fourth electrode), a source electrode 14 (a third electrode), a gate draw-out wiring part 15 (a first wiring part), a FP draw-out interconnect 16, a termination conductive film 17, a gate wiring part 18, a FP wiring part 19, an insulating member 31, an insulating thin film 32 (a first insulating film), an insulating thick film 33 (a second insulating film), and an inter-layer insulating film 34.

In FIG. 1, the semiconductor part 20, the gate electrode 12, the FP electrode 13, the gate draw-out wiring part 15, the FP draw-out interconnect 16, the termination conductive film 17, the insulating member 31, the insulating thin film 32, and the insulating thick film 33 are illustrated, and the source electrode 14, the gate wiring part 18, the FP wiring part 19, and the inter-layer insulating film 34 are not illustrated. FIG. 1 shows a region in which the edge 1e of the semiconductor device 1 is at the left side of the illustration; and the termination region Re, the draw-out region Rd, and the cell region Rc are arranged in this order toward the right side of the illustration.

The semiconductor part 20 is located on the drain electrode 11. The semiconductor part 20 is made of a semiconductor material, includes, for example, silicon (Si), and is formed of, for example, single-crystal silicon. In the semiconductor part 20, the conductivity type and carrier concentration of each portion is controlled by selectively introducing an impurity. The detailed configuration of the semiconductor part 20 is described below.

Multiple insulating members 31 are included. Each insulating member 31 is located in the upper portion of the semiconductor part 20 in the cell region Rc and the draw-out region Rd and extends in one direction (an X-direction described below). The upper portion of the semiconductor part 20 is located between the adjacent insulating members 31. For example, the multiple insulating members 31 are arranged periodically to be parallel to each other in a Y-direction described below.

In the cell region Rc, the insulating thin film 32 is located on the semiconductor part 20 on the insulating members 31 and between the insulating members 31. The insulating thin film 32 contacts the semiconductor part 20 and the insulating member 31.

In the draw-out region Rd, the insulating thick film 33 is located on the semiconductor part 20, on the insulating member 31, and between the insulating members 31. The insulating thick film 33 contacts the semiconductor part 20, the insulating member 31, and the insulating thin film 32. The insulating thick film 33 is located at the termination region Re side with respect to the insulating thin film 32. The insulating thick film 33 is thicker than the insulating thin film 32 and thinner than the insulating member 31.

The insulating member 31, the insulating thin film 32, and the insulating thick film 33 are made of insulating materials and include, for example, silicon oxide (SiO). As shown in FIG. 4, on the semiconductor part 20, the lower surface of the insulating thick film 33 and the lower surface of the insulating thin film 32 are at substantially the same level. On the other hand, the upper surface of the insulating thick film 33 is positioned higher than the upper surface of the insulating thin film 32. Therefore, a step 35 is formed at the boundary between the upper surface of the insulating thin film 32 and the upper surface of the insulating thick film 33.

An XYZ orthogonal coordinate system is employed for convenience of description in the specification hereinbelow. The direction in which the insulating members 31 extend is taken as the “X-direction” (a first direction); the arrangement direction of the multiple insulating members 31 is taken as the “Y-direction” (a second direction); and the direction from the drain electrode 11 toward the source electrode 14 is taken as a “Z-direction” (a third direction). Although the Z-direction also is called “up/above/higher than”, and the opposite direction also is called “down/below/lower than”, these expressions are for convenience and are independent of the direction of gravity.

The gate electrode 12 and the FP electrode 13 each are located in the insulating member 31 and extend in the X-direction. In each insulating member 31, the gate electrode 12 and the FP electrode 13 are arranged along the Y-direction; and one FP electrode 13 is located between two gate electrodes 12. The FP electrode 13 is insulated from the gate electrode 12 by the insulating member 31. The lower end of the FP electrode 13 is positioned lower than the lower end of the gate electrode 12. The X-direction end portion of the FP electrode 13 is positioned at the termination region Re side of the X-direction end portion of the gate electrode 12. The gate electrode 12 and the FP electrode 13 are made of conductive materials and are made of, for example, polysilicon including an impurity.

In the draw-out region Rd, the gate draw-out wiring part 15 is located on the insulating member 31 and on the insulating thick film 33. The gate draw-out wiring part 15 is not located on the insulating thin film 32. The gate draw-out wiring part 15 is made of a conductive material and is made of, for example, polysilicon including an impurity. The gate draw-out wiring part 15 is connected to at least one X-direction end portion of the gate electrode 12. In the specification, “connected” means an electrical connection. Specifically, the lower surface of the portion of the gate draw-out wiring part 15 at the cell region Rc side is formed to have a continuous body with the upper surface of the portion of the gate electrode 12 at the termination region Re side.

In the draw-out region Rd, the FP draw-out interconnect 16 is located on the insulating member 31 and on the insulating thick film 33. The FP draw-out interconnect 16 is not located on the insulating thin film 32. The FP draw-out interconnect 16 is located at the termination region Re side of the gate draw-out wiring part 15 and is separated from the gate draw-out wiring part 15. The FP draw-out interconnect 16 is made of a conductive material and is made of, for example, polysilicon including an impurity. The FP draw-out interconnect 16 is connected to the X-direction end portion of the FP electrode 13. Specifically, the lower surface of the portion of the FP draw-out interconnect 16 at the cell region Rc side is formed to have a continuous body with the upper surface of the portion of the FP electrode 13 at the termination region Re side.

The termination conductive film 17 is located on the insulating thick film 33 at the portion of the termination region Re at the draw-out region Rd side. The termination conductive film 17 is separated from the FP draw-out interconnect 16. The termination conductive film 17 is made of, for example, polysilicon including an impurity.

The inter-layer insulating film 34 is located on the insulating member 31, on the insulating thin film 32, and on the insulating thick film 33 in the cell region Rc, the draw-out region Rd, and the portion of the termination region Re at the draw-out region Rd side. The inter-layer insulating film 34 covers the gate draw-out wiring part 15, the FP draw-out interconnect 16, and the termination conductive film 17.

In the draw-out region Rd, the gate wiring part 18 is located on the inter-layer insulating film 34. The gate wiring part 18 is located in a region overlapping the gate draw-out wiring part 15 when viewed from above, and is connected to the gate draw-out wiring part 15 via a gate contact 18a extending through the inter-layer insulating film 34. The gate draw-out wiring part 15 is connected to a gate pad (not illustrated) located on the inter-layer insulating film 34. Therefore, the gate electrode 12 is connected to the gate pad via the gate draw-out wiring part 15 and the gate wiring part 18.

In the draw-out region Rd, the FP wiring part 19 is located on the inter-layer insulating film 34. The gate wiring part 18 is located in a region overlapping the FP draw-out interconnect 16 when viewed from above, and is connected to the FP draw-out interconnect 16 via a FP contact 19a extending through the inter-layer insulating film 34.

In the cell region Rc, the source electrode 14 is located on the inter-layer insulating film 34. Accordingly, the source electrode 14 is located on the semiconductor part 20, on the insulating member 31, and on the insulating thin film 32. The source electrode 14 is connected to the semiconductor part 20 via a source contact 14a extending through the inter-layer insulating film 34. The source electrode 14 also is connected to the FP wiring part 19. As a result, the FP electrode 13 is connected to the source electrode 14 via the FP draw-out interconnect 16 and the FP wiring part 19.

An insulating protective film (not illustrated) is located on the semiconductor part 20, on the inter-layer insulating film 34, on the gate wiring part 18, on the FP wiring part 19, and on the source electrode 14. However, a portion of the source electrode 14 and a portion of the gate pad (not illustrated) are not covered with the protective film and form regions to which external wiring parts are bonded.

The semiconductor part 20 includes a drain layer 21, a drift layer 22, a base layer 23, a base contact layer 24, a source layer 25, a source contact layer 26, a termination p-type layer 28, and a termination n-type layer 29.

The drain layer 21 is located on the entire surface of the drain electrode 11 and contacts the drain electrode 11. The conductivity type of the drain layer 21 is the n⁺-type. The drift layer 22 is located on the entire surface of the drain layer 21 and contacts the drain layer 21. The conductivity type of the drift layer 22 is the n⁻-type. The “n⁺-type” refers to a higher carrier concentration than the “n-type”; and the “n⁻-type” refers to a lower carrier concentration than the “n-type”. This is similar for the p-type as well. A first semiconductor layer is formed of the drain layer 21 and the drift layer 22.

In the cell region Rc, the base layer 23 is located on a portion of the drift layer 22. The base layer 23 faces the gate electrode 12 via the insulating member 31. The conductivity type of the base layer 23 is the p-type. The base contact layer 24 is located between the base layer 23 and the source electrode 14 and contacts the base layer 23 and the source electrode 14. The conductivity type of the base contact layer 24 is the p⁺-type. The base layer 23 is connected to the source contact 14a of the source electrode 14 via the base contact layer 24. The base layer 23 and the base contact layer 24 are separated from the gate draw-out wiring part 15 when viewed from above. A second semiconductor layer is formed of the base layer 23 and the base contact layer 24.

The source layer 25 is located in a region on the base layer 23 and contacts the insulating member 31. The conductivity type of the source layer 25 is the n-type. The source contact layer 26 is located between two adjacent source layers 25 on the base layer 23. The source contact layer 26 contacts the base layer 23 and the source layer 25 and is separated from the insulating member 31. The conductivity type of the source contact layer 26 is the n⁺-type. The upper surface of the source layer 25 and the upper surface of the source contact layer 26 contact the lower surface of the source contact 14a of the source electrode 14. As a result, the source layer 25 and the source contact layer 26 are connected to the source electrode 14. A third semiconductor layer is formed of the source layer 25 and the source contact layer 26.

In the termination region Re, the termination p-type layer 28 is located on the drift layer 22. The conductivity type of the termination p-type layer 28 is the p-type. The termination n-type layer 29 is located on a portion of the termination p-type layer 28 and is separated from the drift layer 22 via the termination p-type layer 28. The conductivity type of the termination n-type layer 29 is the n⁺-type.

Effects of the embodiment will now be described.

In the semiconductor device 1, when an on-potential, e.g., a positive potential, is applied to the gate electrode 12 in a state in which a source potential, e.g., a ground potential, is applied to the source electrode 14 and a drain potential that is higher than the source potential is applied to the drain electrode 11, an inversion layer is formed in the portion of the base layer 23 contacting the insulating member 31; and the semiconductor device 1 is set to an on-state. As a result, a current flows between the source and drain.

On the other hand, when an off-potential, e.g., the ground potential, is applied to the gate electrode 12, the inversion layer disappears, and the semiconductor device 1 is switched to an off-state. The current between the source and drain is blocked thereby. At this time, the drain layer 21, the drift layer 22, and the base layer 23 have the drain potential.

In the semiconductor device 1, the gate draw-out wiring part 15 is separated from the drift layer 22 via the insulating thick film 33 that is thicker than the insulating thin film 32, and is therefore not easily affected by the potential of the drift layer 22. Also, the gate draw-out wiring part 15 is separated from the base layer 23 and the base contact layer 24 when viewed from above, and is therefore not easily affected by the potential of the base layer 23. As a result, an increase of the potential of the gate electrode 12 from the off-potential due to capacitive coupling can be suppressed, and leakage current in the off-state can be reduced.

### Comparative Example

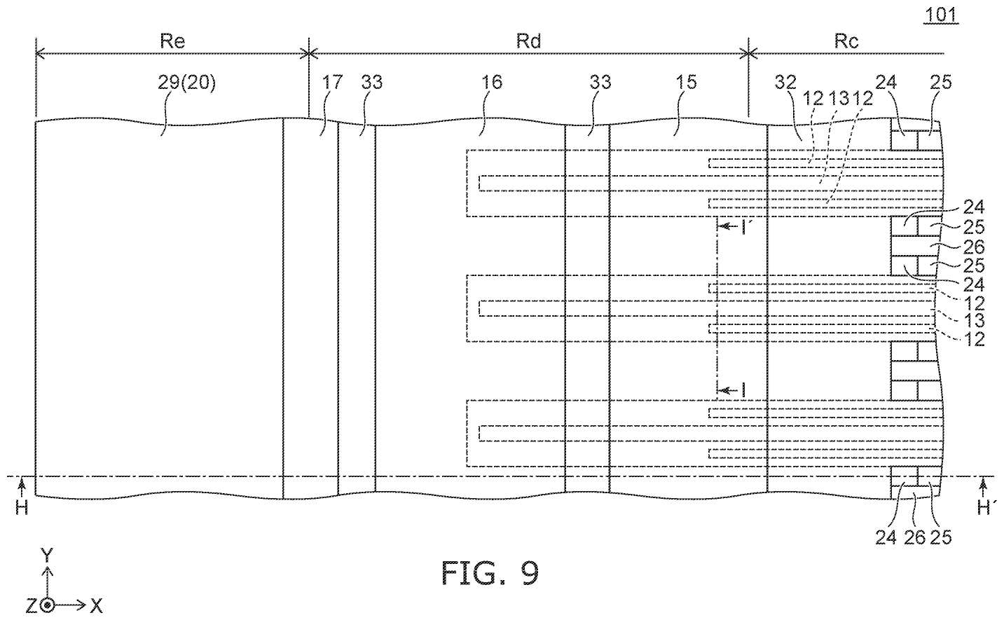

FIG. 9 is a plan view showing a semiconductor device according to the comparative example.

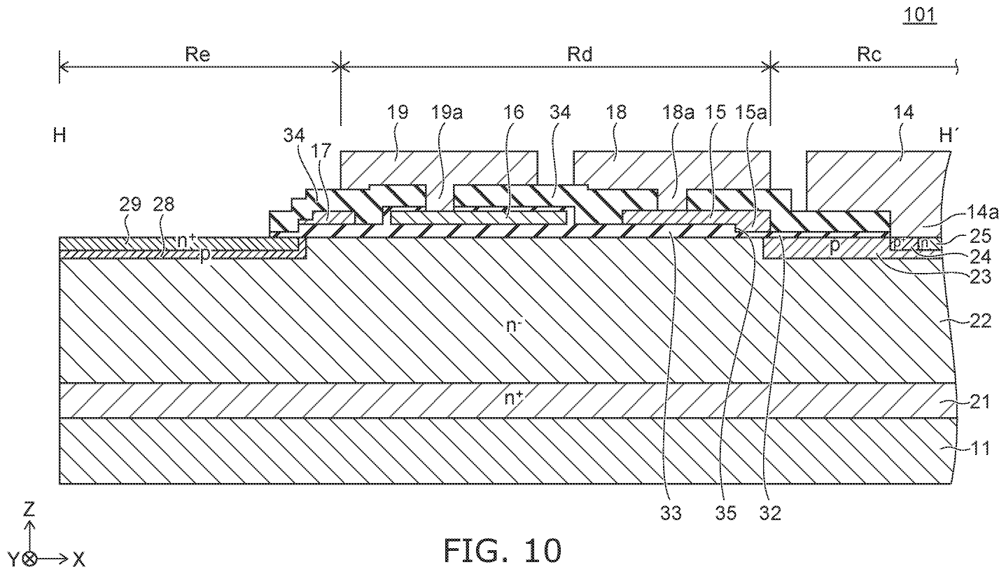

FIG. 10 is a cross-sectional view along line H-H′ shown in FIG. 9.

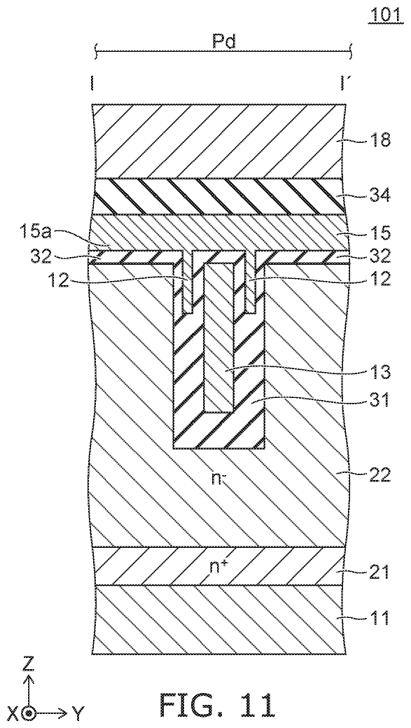

FIG. 11 is a cross-sectional view along line I-I′ shown in FIG. 9.

In the semiconductor device 101 according to the comparative example as shown in FIGS. 9 to 11, a portion 15a of the gate draw-out wiring part 15 at the cell region Rc side is located on the insulating thin film 32. As a result, the gate draw-out wiring part 15 faces the base layer 23 and the drift layer 22 via the insulating thin film 32.

Therefore, when the semiconductor device 101 is switched to the off-state, the gate draw-out wiring part 15 is capacitively coupled with the base layer 23 and the drift layer 22; and the potential of the gate draw-out wiring part 15 undesirably exceeds the off-potential. As a result, the potential of the gate electrode 12 also exceeds the off-potential; and the leakage current undesirably increases.

According to the embodiments described above, a semiconductor device can be realized in which the leakage current can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a semiconductor part located on the first electrode;
an insulating member located in the semiconductor part;
a first insulating film located on a portion of the semiconductor part;
a second insulating film located on another portion of the semiconductor part, the second insulating film being thicker than the first insulating film;
a second electrode located in the insulating member;
a first wiring part connected to the second electrode, the first wiring part being located on the insulating member and on the second insulating film but not on the first insulating film; and
a third electrode located on the semiconductor part, on the insulating member, and on the first insulating film.

2. The device according to claim 1, further comprising:
a fourth electrode located in the insulating member, the fourth electrode being insulated from the second electrode and connected to the third electrode.

3. The device according to claim 2, wherein
the insulating member extends in a first direction,
the second electrode and the fourth electrode are arranged along a second direction orthogonal to the first direction in the insulating member,
the first direction and the second direction cross a third direction, and
the third direction is from the first electrode toward the third electrode.

4. The device according to claim 1, wherein
the second insulating film is positioned at a termination side of the insulating member with respect to the first insulating film.

5. The device according to claim 1, wherein
the insulating member contacts the first and second insulating films.

6. The device according to claim 1, wherein
the semiconductor part includes:
a first semiconductor layer connected to the first electrode, the first semiconductor layer being of a first conductivity type;
a second semiconductor layer located on a portion of the first semiconductor layer, the second semiconductor layer facing the second electrode via the insulating member, the second semiconductor layer being of a second conductivity type; and
a third semiconductor layer located on a portion of the second semiconductor layer, the third semiconductor layer being connected to the third electrode, the third semiconductor layer being of the first conductivity type.

7. The device according to claim 6, wherein
the second semiconductor layer is separated from the first wiring part when viewed from above.

8. The device according to claim 1, wherein
the semiconductor part includes silicon, and
the insulating member, the first insulating film, and the second insulating film include silicon oxide.

9. A semiconductor device, comprising:
a first electrode;
a first semiconductor layer located on the first electrode, the first semiconductor layer being of a first conductivity type;
a second semiconductor layer located on a portion of the first semiconductor layer, the second semiconductor layer being of a second conductivity type;
a third semiconductor layer located on a portion of the second semiconductor layer, the third semiconductor layer being of the first conductivity type;
a second electrode facing the second semiconductor layer via an insulating member;
a first wiring part located on the first semiconductor layer, the first wiring part being connected to the second electrode, the first wiring part being separated from the second semiconductor layer when viewed from above;
a fourth electrode located in the insulating member, the fourth electrode being insulated from the second electrode; and
a third electrode connected to the third semiconductor layer and the fourth electrode.
